(19) United States
(12) Patent Application Publication
(10) Pub. No.: US 2008/0055824 A1
(43) Pub. Date: Mar. 6, 2008

(54) Battery powered device having a protective frame

(75) Inventors: Robert W. Singleton, Lakeland, FL (US); Lawrence J. Keim, Lakeland, FL (US)

Correspondence Address: FOLEY AND LARDNER LLP;SUITE 500, 3000 K STREET NW, WASHINGTON, DC, 20007, US

(73) Assignee: Innovatier, Inc.

(21) Appl. No.: 11/509,817

(22) Filed: Aug. 25, 2006

(51) Int. Cl. H05K 5/00; H02B 1/00

(52) U.S. Cl. 361/679; 361/600

(57) ABSTRACT

A battery powered device is composed of a plurality of circuit components, including a battery. The perimeter of the battery is enclosed by a protective frame. The protective frame prevents the battery from being severely damaged by tearing or cutting forces commonly used in the destruction and disposal of battery powered devices.

### BACKGROUND OF THE INVENTION

The following description of the background of the invention is provided simply as an aid in understanding the invention and is not admitted to describe or constitute prior art to the invention.

Generally, batteries can be used for various applications such as powering smart cards, radio frequency identification (“RFID”) tags or other small consumer devices requiring a small, internal power source. These battery powered devices may be used as credit cards, bankcards, ID cards, telephone cards, security cards or similar devices. Battery powered devices of this type are generally constructed by assembling several layers of plastic sheets in a sandwich-like array. In the alternative, the above-mentioned battery powered devices may be produced using an injection molding process or similar techniques. A battery is embedded into these devices to power the device's circuitry, which allows the device to perform a number of functions.

Portable battery powered devices such as smart cards are readily available to consumers. The battery powered devices can include replaceable batteries or can be configured for temporary use. Temporary devices are typically disposed of by the consumer when the battery powering the device is drained. Generally, consumers dispose of these battery powered devices in the home or workplace by placing the battery powered device in the trash. Where a battery powered device such as a smart card may contain sensitive information and/or could be used to access a secure area or proprietary device, a consumer will generally destroy the device in the process of disposing of it. Destroying the device prevents it from being used by unauthorized persons.

A common method for disposing of such devices is to cut the device using scissors or a knife. In addition, a consumer may insert the device into a shredder to destroy the device. Alternatively, the consumer may use force such as tearing or ripping to destroy the battery device. However, during the cutting or shredding process, the battery of the device may be cut or severely damaged. Consequently, the damaged battery may leak harmful chemicals such as battery electrolyte or lithium metal. For example, there have been several accounts of consumers destroying battery powered devices with scissors, causing harmful chemicals to leak on their hands. These chemicals can cause serious harm if they come into contact with a consumer's eyes, an open cut, or if the consumer ingests the chemical. Similarly, other components in the battery powered device may also cause a serious health risk to the consumer if cut or damaged in the above-mentioned ways.

In view of the following, there is a need for a battery powered device that can prevent components embedded in the device, specifically the battery, from being damaged by cutting, tearing or other similar techniques commonly used in the disposal of battery powered devices.

### SUMMARY OF THE INVENTION

According to one embodiment of the invention, a battery powered device includes a battery and a protective frame enclosing the perimeter of the battery.

According to another embodiment of the invention, the protective frame encloses the perimeter and the top surface of the battery.

According to still another embodiment of the invention, a battery powered device includes a plurality of circuit components, including a battery, and a protective frame enclosing one or more of the plurality of circuit components.

According to yet another embodiment of the invention, the protective frame is composed of a metal alloy.

It is to be understood that both the foregoing general description and the following detailed description are exemplary and explanatory only, and are not restrictive of the invention as claimed.

### BRIEF DESCRIPTION OF THE DRAWINGS

These and other features, aspects and advantages of the present invention will become apparent from the following description, appended claims, and the accompanying exemplary embodiments shown in the drawings, which are briefly described below.

FIG. 1 is a profile sectional view of a battery powered device according to one embodiment of the present invention.

FIG. 2 is a top sectional view of a battery powered device according to one embodiment of the present invention.

FIG. 3 is a profile sectional view of a battery powered device according to another embodiment of the present invention.

FIG. 4 is a profile sectional view of a battery powered device according to another embodiment of the present invention.

FIG. 5 is a top sectional view of a battery powered device according to another embodiment of the present invention.

FIG. 6 is a profile sectional view of a battery powered device according to still another embodiment of the invention.

### DETAILED DESCRIPTION

Embodiments of the present invention will be described below with reference to the accompanying drawings. It should be understood that the following description is intended to describe exemplary embodiments of the invention, and not to limit the invention.

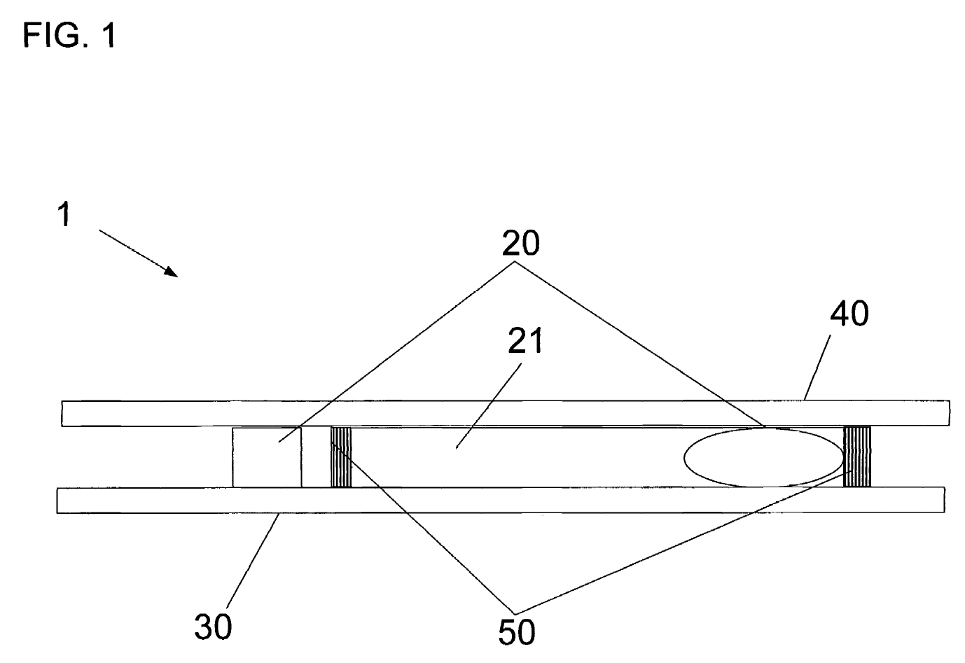

According to one embodiment of the invention, as shown in FIG. 1, a battery powered device 1 comprises a battery 21 enclosed by a protective frame 50. The battery 21 provides power to a plurality of circuit components 20 that are included in the battery powered device 1. The protective frame 50 prevents the battery 21 from being damaged by cutting, tearing, shearing or shredding forces. The protective frame 50 can be composed of any rigid material resistant to tearing, shearing, cutting or similar forces. Preferably, the protective frame 50 is composed of a metal alloy. Specifically, the protective frame 50 may be made of stainless steel. In the alternative, the protective frame 50 may be composed of cut resistant fibers. For example the protective frame 50 may be composed of para-aramid fibers. Para-aramid fibers are low-weight synthetic fibers that have a high tensile strength and high cut resistance. Kevlar® is a well known brand of para-aramid fiber. As shown in FIG. 1, the protective frame is positioned along the perimeter edge of the battery 21 by using an adhesive to fasten the overlay and circuit board.

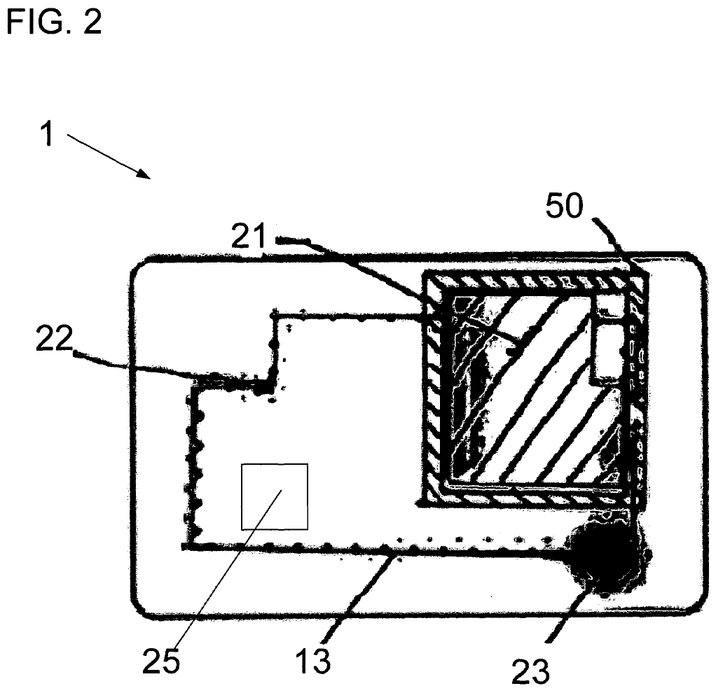

FIG. 2 is a top sectional view of an embodiment of a battery powered device 1 shown in FIG. 1. FIG. 2 shows a more detailed battery powered device with circuit traces 13 and having exemplary circuit components 20 such as a LED 22, a button 23, and a speaker 25. The protective frame 50, shown in FIG. 2, is positioned around the entire perimeter of the battery 21. The protective frame 50 can have a variable thickness. The thickness is dependent upon the physical characteristics and position of the battery 21 in the battery powered device 1. Preferably, the protective frame 50 has a thickness in the range of 0.010-0.022 inches. The protective frame 50 prevents the battery 21 from being severely damaged or cut by scissors, shredding devices or other forces and instruments commonly used by consumers to destroy disposable electronic devices and the like. In turn, upon destruction of the card, the battery 21 does not leak harmful chemicals that could be exposed to consumers.

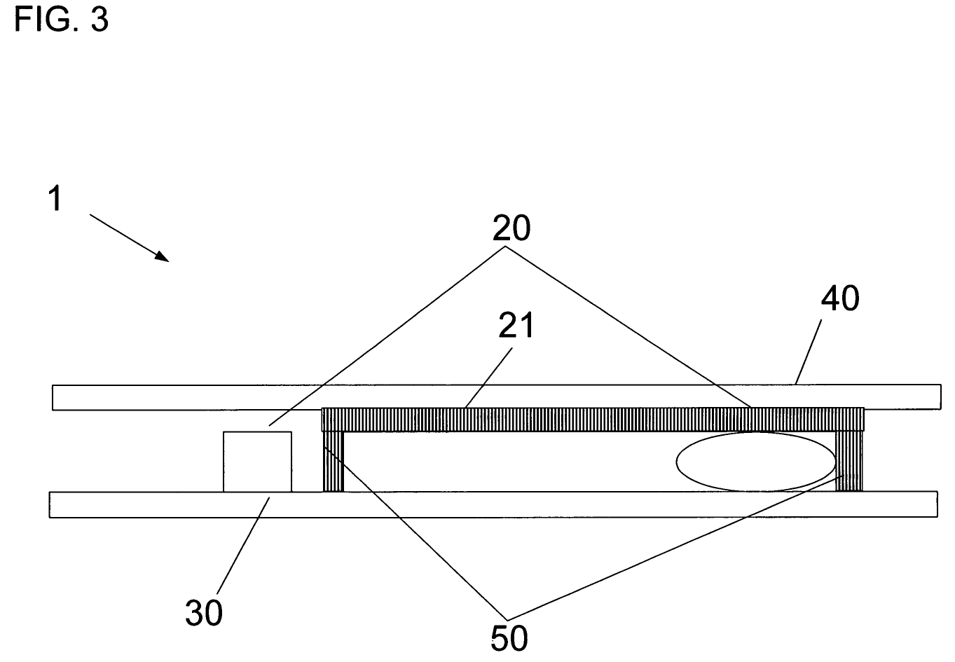

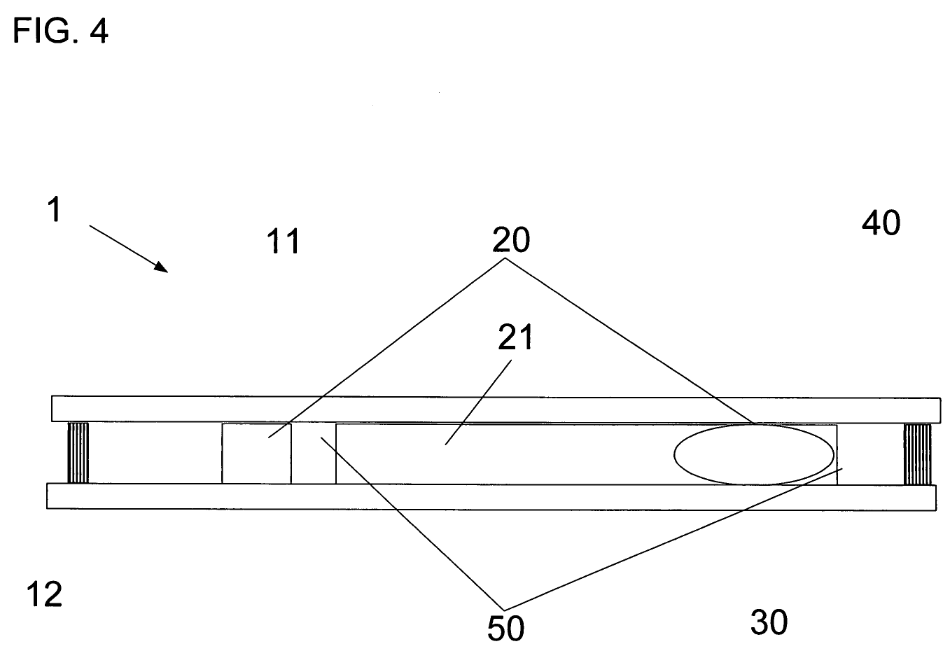

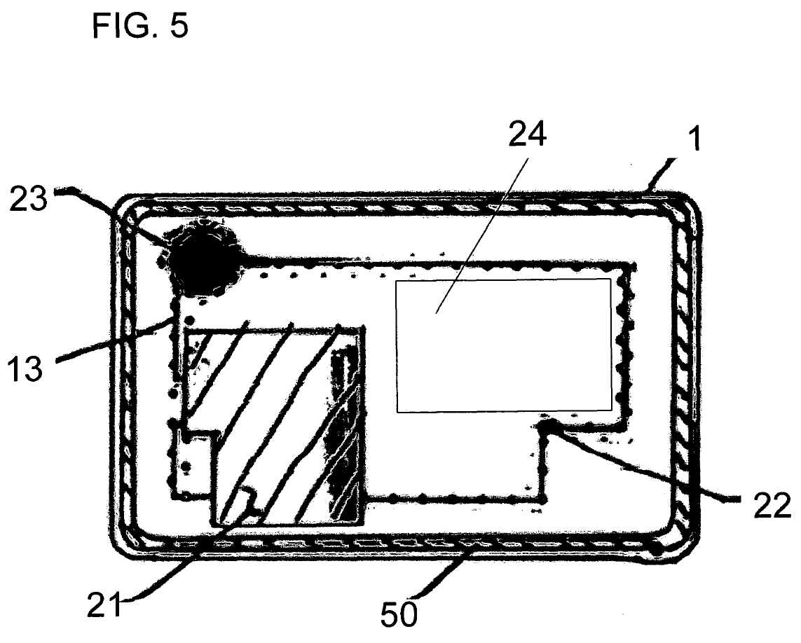

According to another embodiment of the invention, as shown in FIG. 3, the protective frame 50 may also cover the top surface of the battery 21. In this embodiment the protective frame 50 provides additional protection from any destructive forces being applied to the top surface of the battery 21. According to still another embodiment of the invention, the protective frame 50 may be positioned along the peripheral edge of the entire battery powered device 1. This embodiment is shown for example in FIGS. 4 and 5. In this embodiment, the entire battery powered device 1 is protected from commonly used consumer disposal methods. The protective frame 50 encloses every circuit component 20 in the battery powered device 1, thus preventing the battery 21 and other circuit components 20 from being severely damaged by cutting or tearing. For example, the battery powered device 1 shown in FIG. 5 may include a liquid crystal display 24. The liquid crystal display 24 may be used to display information to a user, such as an account balance. Similar to the battery 21, the liquid crystal display 24 may contain substances that are harmful to consumers. Thus, the protective frame 50 shown in FIG. 5 will also protect the liquid crystal display from being severely damaged by cutting or tearing.

Exemplary constructions of a battery powered device 1 having a protective frame 50 are described below in further detail. The battery powered devices 1 may be constructed using any one of several techniques such as heat lamination and injection molding for producing products such as smart cards, tags and wristbands. As shown in FIGS. 1, 2 and 4 the battery 21, protective frame 50 and the plurality of circuit components 20 may be positioned on a bottom overlay 30. The battery powered device 1 also includes a top overlay 40 which is positioned above the battery 21 and circuit components 20.

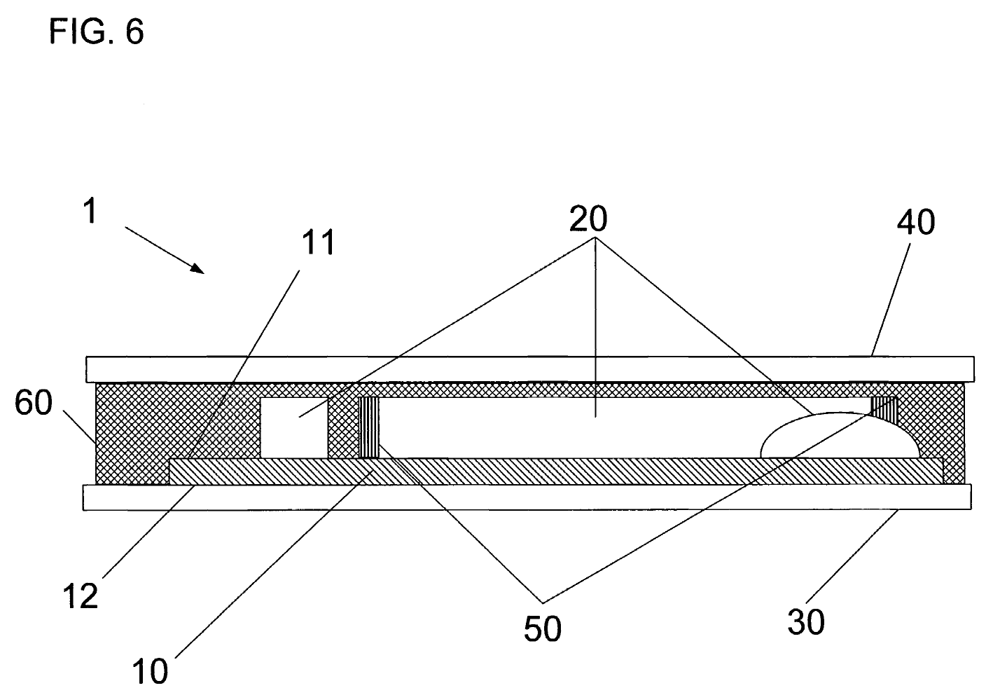

In the alternative, as shown in FIG. 6, the battery 21, protective frame 50 and plurality of circuit components 20 may be positioned on a printed circuit board 10, which is then attached to the bottom overlay 30. According to one embodiment of the invention, as shown in FIG. 6, a core layer 60 may surround the battery 21 and circuit components 20.

The printed circuit board 10 has a top surface 11 and a bottom surface 12. The printed circuit board 10 may be comprised of any known conventional material suitable for receiving an electronic circuit. For example, the printed circuit board 10 may be comprised of a flame retardant laminate with a woven glass reinforced epoxy resin. This material is also known as FR-4 board. Alternatively, the printed circuit board 10 may be comprised of a plastic compound that is suitable for receiving conductive ink. As shown in FIG. 6 and described below, the printed circuit board 10 is configured to receive and vertically stabilize the battery 21 and a plurality of circuit components 20.

A plurality of circuit traces 13 (shown in FIGS. 2 and 5) may reside on the top surface 11 of the printed circuit board 10, or on the top surface of the bottom overlay 30. The circuit traces 13 are configured to contact the plurality of circuit components 20. The circuit traces 13 electrically connect to the plurality of circuit components 20 such that the circuit components 20 are capable of performing various functions within the battery powered device 1. The circuit traces 13 may be formed on the printed circuit board 10 or bottom overlay 30 by any one of a number of methods. For example, the circuit traces 13 may be formed by an etching process where conductive material is etched to form the traces 13. As another example, the circuit traces 13 may be formed with conductive ink.

The battery 21 and the plurality of circuit components 20 may be attached to the circuit traces on the printed circuit board 10 or bottom overlay 30 by any one of a number of methods. For example, in one embodiment of the invention, the circuit components 20 are connected to the printed circuit board 10 or bottom overlay 30 with a conductive adhesive. Preferably, the plurality of circuit components 20 are soldered onto the printed circuit board 10 or bottom overlay 30. The plurality of circuit components 20 can be positioned anywhere on the printed circuit board 10 or bottom overlay 30. The purpose of the battery powered device 1 and design parameters will dictate the position of the circuit traces 13 and the position of the circuit components 20. Functionality will also dictate what types of circuit components 20 populate the battery powered device 1.

For example purposes only, the plurality of circuit components 20 could be one of a battery 21, a button 23, a microprocessor chip 26 or LEDs 22. Any one or all of these circuit components 20 could populate the battery powered device 1. Further, additional circuit components 20 may include but are not limited to, speakers 25, flexible displays 24, RFID antennas and emulators.

Generally, the circuit components 20 shown in FIGS. 1-6 may vary in thickness and length. For example purposes only, the battery 21 has a thickness of 0.016 inches, the push button 23 has a thickness of 0.020 inches and the LED 22 has a thickness of 0.015 inches. In addition, the battery powered device 1 shown in FIG. 2 could have a speaker 25 having a thickness of 0.010 inches. The protective frame 50 is of sufficient thickness to enclose and protect the battery 21. In the alternative, the protective frame 50 is of sufficient thickness to enclose and protect all the circuit components 20 in the battery powered device 1.

As shown in FIG. 6, a bottom overlay 30 may be attached to the bottom surface 12 of the printed circuit board 10. The bottom overlay 30 can be attached to the printed circuit board 10 by any number of known methods. Preferably, the bottom surface 12 is attached to the bottom overlay 30 using a pressure sensitive adhesive tape or a spray-on adhesive. The bottom overlay 30 may be comprised of any suitable material, but preferably, the bottom overlay 30 is comprised of polyvinyl chloride (PVC) or like material. According to one embodiment of the invention, printed information may be placed on the outside surface of the bottom overlay 30. For example, the bottom overlay 30 may include printed information consistent with a standard credit card or identification tag, including a name, expiration date and account number. According to another embodiment of the invention, the bottom overlay 30 may be clear or ⅖ clear/white printed. Specifically, a 0.002 inch thick piece of clear PVC material is laminated on to a layer of white PVC that is 0.005 inches in thickness.

A top overlay 40 positioned above the circuit components 20 is shown in FIGS. 1, 3, 4 and 6. The top overlay 40 may be comprised of any suitable material, for example, the top overlay 40 may be comprised of polyvinyl chloride (PVC) or like material. According to one embodiment of the invention, the outside surface of the top overlay 40 may have printed information. For example, the top overlay 40 may include printed information consistent with a standard credit card or identification tag, including a name, expiration date and account number. According to another embodiment of the invention, the top overlay 40 may be clear or “⅖ clear/white printed.”

As shown in FIG. 6, a core layer 60 may be positioned between the top surface 11 of the printed circuit board 10 and the top overlay 40. Preferably, the core layer 60 is composed of a thermosetting polymeric material. Due to its bonding and adhesive properties, a core thermosetting polymeric layer 60 integrates the top overlay 40 with the remaining components to form the battery powered device 1.

The present invention has several advantages. One advantageous feature is that one or more circuit components can be enclosed by a protective frame. The protective frame protects sensitive circuit components from physical damage. Specifically, the protective frame prevents circuit components such as the battery from being cut or damaged by common instruments such as scissors. This prevents harmful chemicals other undesirable agents from leaking from the battery when the battery powered device is destroyed or disposed of.

The foregoing description of a preferred embodiment of the invention has been presented for purposes of illustration and description. It is not intended to be exhaustive or to limit the invention to the precise form disclosed, and modifications and variations are possible in light of the above teaching or may be acquired from practice of the invention. The embodiment was chosen and described in order to explain the principles of the invention and as a practical application to enable one skilled in the art to utilize the invention in various embodiments and with various modification are suited to the particular use contemplated. It is intended that the scope of the invention be defined by the claims appended hereto and their equivalents.

What is claimed is:

1. A battery powered device, comprising:
a battery; and
a protective frame enclosing the perimeter of the battery.

2. The battery powered device of claim 1, wherein the protective frame encloses the top surface of the battery.

3. The battery powered device of claim 1, wherein the protective frame is composed of a metal alloy.

4. A battery powered device, comprising:
a plurality of circuit components including a battery; and
a protective frame enclosing one or more of the plurality of circuit components.

5. The battery powered device of claim 4, wherein the protective frame is positioned along the periphery of the battery powered device.

6. The battery powered device of claim 4, wherein the protective frame only encloses the perimeter of the battery.

7. The battery powered device of claim 4, wherein the protective frame is composed of a metal alloy.
